(19) United States
(12) Patent Application Publication
(10) Pub. No.: US 2025/0324713 A1
(43) Pub. Date: Oct. 16, 2025

(54) SEMICONDUCTOR DEVICE AND METHOD FOR FABRICATING THE SAME

(71) Applicant: SK hynix Inc., Gyeonggi-do (KR)

(72) Inventors: Yoon Jae NAM, Gyeonggi-do (KR); Eun Tae KIM, Gyeonggi-do (KR); Seong Wan RYU, Gyeonggi-do (KR); Jong Kook PARK, Gyeonggi-do (KR); Jae Sang LEE, Gyeonggi-do (KR); Sung Hwan HWANG, Gyeonggi-do (KR)

(21) Appl. No.: 18/929,614

(22) Filed: Oct. 29, 2024

(30) Foreign Application Priority Data
Apr. 12, 2024 (KR) 10-2024-0049280

(51) Int. Cl. H01L 29/423; H01L 29/49; H01L 29/51

(52) U.S. Cl. CPC H10D 64/513; H10D 64/664; H10D 64/693

(57) ABSTRACT

A semiconductor device includes a trench formed in a substrate; a first gate filled in a lower portion of the trench; and a second gate disposed over the first gate, wherein each of the first gate and the second gate contains oxygen material, and an oxygen content of the first gate is greater than an oxygen content of the second gate.

### CROSS-REFERENCE TO RELATED APPLICATIONS

The present application claims priority under 35 U.S.C 119 (a) to Korean Patent Application No. 10-2024-0049280, filed on Apr. 12, 2024, which is incorporated herein by reference in its entirety.

### BACKGROUND

### 1. Field

Embodiments of the present invention relate to a semiconductor device and a method for fabricating the same, and more particularly, to a semiconductor device including buried gates, and a method for fabricating the semiconductor device.

### 2. Description of the Related Art

Metal gate electrodes are used to ensure high performance of transistors. To be specific, buried gate-type transistors require controlling a threshold voltage for high-performance operation. Gate-Induced Drain Leakage (GIDL) characteristics may significantly affect the performance of the buried gate-type transistors.

### SUMMARY

Embodiments of the present invention are directed to a semiconductor device with improved electrical characteristics.

In accordance with an embodiment of the present invention, a semiconductor device includes a trench formed in a substrate; a first gate filled in a lower portion of the trench; and a second gate over the first gate, wherein each of the first gate and the second gate contains oxygen material, and an oxygen content of the first gate is greater than an oxygen content of the second gate.

In accordance with another embodiment of the present invention, a method for fabricating a semiconductor device includes forming a trench in a substrate; forming a first gate that fills a lower portion of the trench; forming a second gate over the first gate; forming a sacrificial layer over the second gate; substituting a surface of the second gate with silicon oxide by performing a heat treatment; and removing the sacrificial layer and the silicon oxide, wherein each of the first and second gates contains oxygen material, and an oxygen content of the first gate is greater than an oxygen content of the second gate.

### BRIEF DESCRIPTION OF THE DRAWINGS

FIG. 1 is a plan view illustrating a semiconductor device in accordance with embodiments of the present invention.

FIG. 2A is a cross-sectional view of a semiconductor device taken along a line A-A′ shown in FIG. 1 in accordance with a first embodiment of the present invention.

FIG. 2B is a cross-sectional view of the semiconductor device taken along a line B-B′ shown in FIG. 1 in accordance with the first embodiment of the present invention.

FIGS. 3 to 13 are cross-sectional views illustrating semiconductor devices in accordance with second to 12^{th} embodiments of the present invention, respectively.

FIG. 14 is a plan view illustrating a semiconductor device in accordance with a 13^{th} embodiment of the present invention.

FIG. 15 is a cross-sectional view of the semiconductor device taken along a line I-I′ shown in FIG. 14 in accordance with the 13^{th} embodiment of the present invention.

FIGS. 16A to 16D are process cross-sectional views illustrating a method for fabricating a semiconductor device in accordance with a first embodiment of the present invention.

FIGS. 17A to 17E are process cross-sectional views illustrating a method for fabricating a semiconductor device in accordance with a fourth embodiment of the present invention.

### DETAILED DESCRIPTION

Embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being ‘on’ a second layer or ‘on’ a substrate, it not only may refer to a case where the first layer is formed directly over the second layer or the substrate but also a case where a third layer exists between the first layer and the second layer or the substrate.

Hereinafter, in the following embodiments of the present invention, a threshold voltage Vt may depend on a flat-band voltage VFB. The flat band voltage VFB may depend on a work function. The work function may be engineered by diverse methods. For example, the work function may be adjusted by a material of a gate electrode and a material between the gate electrode and a channel. The flat band voltage may be shifted by increasing or decreasing the work function. A high work function may shift the flat band voltage in a positive direction, and a low work function may shift the flat band voltage in a negative direction. As described above, the threshold voltage may be adjusted by shifting the flat band voltage. According to the embodiments of the present invention, even though the concentration of the channel is decreased or a channel doping process is skipped, the threshold voltage may be adjusted by shifting the flat band voltage.

In the following embodiments of the present invention, a buried gate structure may be disposed in a trench. The buried gate structure may include a gate dielectric layer and a gate electrode. The gate dielectric layer may cover the surface of the trench, and the gate electrode may fill a portion of the trench over the gate dielectric layer. Therefore, the gate electrode may be referred to as a ‘buried gate electrode.’ The gate electrode may include a lower buried gate LBG and an upper buried gate UBG. The lower buried gate may fill the lower portion of the trench, and the upper buried gate may fill the upper portion of the trench over the lower buried gate. As described above, the gate electrode may be a dual gate electrode in which the upper buried gate is disposed over the lower buried gate. The lower buried gate may overlap with the channel, and the upper buried gate may overlap with the first and second doped regions (i.e., source/drain regions).

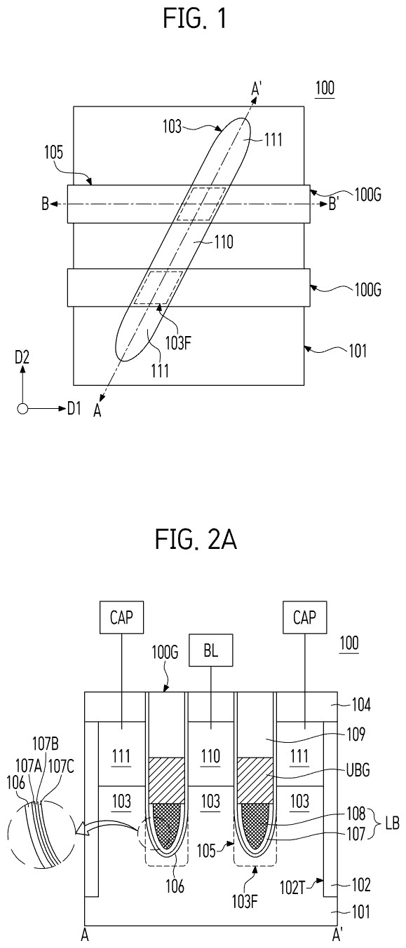

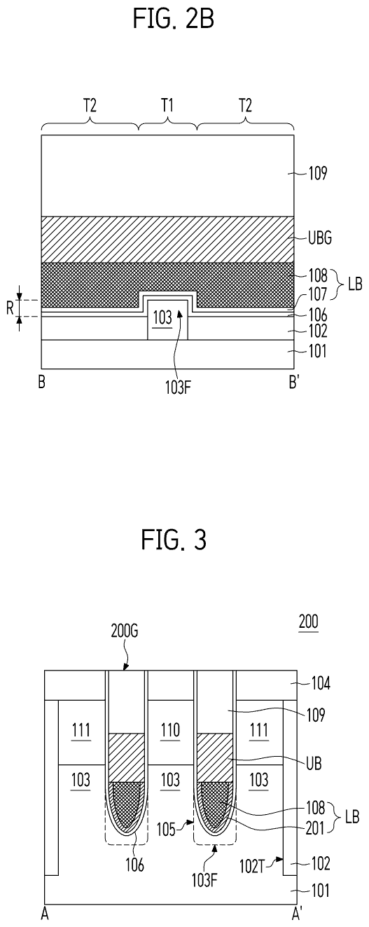

FIG. 1 is a plan view illustrating a semiconductor device 100 in accordance with the embodiments of the present invention. FIG. 2A is a cross-sectional view of the semiconductor device 100 taken along a line A-A′ shown in FIG. 1 in accordance with a first embodiment of the present invention. FIG. 2B is a cross-sectional view of the semiconductor device 100 taken along a line B-B′ shown in FIG. 1 in accordance with the first embodiment of the present invention.

Referring to FIGS. 1, 2A, and 2B, the semiconductor device 100 may include a substrate 101, and a buried gate structure 100G, a first doped region 110 and a second doped region 111 that are embedded in the substrate 101. The buried gate structure 100G and the first and second doped regions 110 and 111 may form a cell transistor. The cell transistor may improve a short channel effect due to the buried gate structure.

The semiconductor device 100 may be a portion of a memory cell. For example, the semiconductor device 100 may be a portion of a memory cell of a dynamic random access memory (DRAM). The semiconductor device 100 may include a bit line BL and a memory storage element CAP that are electrically connected to the substrate 101. The bit line BL may be coupled to the first doped region 110, and the memory storage element CAP may be coupled to the second doped region 111. The bit line BL and the memory storage element CAP may be disposed at a higher level than the buried gate structure 100G. The bit line BL and the memory storage element CAP may be disposed at different levels. The memory storage element CAP may be disposed at a higher level than the bit line BL. The memory storage element CAP may include a capacitor.

The substrate 101 may include a material which is appropriate for semiconductor processing. The substrate 101 may include a semiconductor substrate. The substrate 101 may include a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include other semiconductor materials, such as germanium. The substrate 101 may include a group III-V semiconductor substrate, for example, a compound semiconductor substrate, such as gallium arsenide (GaAs). The substrate 101 may include a Silicon-On-Insulator (SOI) substrate.

An isolation layer 102 and an active region 103 may be formed over the substrate 101. The active region 103 may be defined by the isolation layer 102. The active region 103 may have a long axis and a short axis. The active region 103 may be tilted in a diagonal direction. A pair of buried gate structures 100G that are spaced apart from each other may be formed in one active region 103. The first doped region 110 may be formed in the active region 103 between the pair of buried gate structures 100G. The second doped region 111 may be formed in the active region 103 outside each buried gate structure 100G. This embodiment may present a ‘6F2’ structure including the pair of buried gate structures 100G, one first doped region 110, and two second doped regions 111 in one active region.

The isolation layer 102 may be a Shallow Trench Isolation (STI) region that is formed by a trench etching process. The isolation layer 102 may be formed by filling an isolation trench 102T with a dielectric material. The isolation layer 102 may include silicon oxide, silicon nitride, or a combination thereof.

Two trenches 105 may be formed in the substrate 101. Each of the trenches 105 may be formed by using a hard mask layer 104 as an etch barrier and etching the substrate 101. From the perspective of a top view of FIG. 1, each trench 105 may have a line shape extending in a first direction D1. Each trench 105 may have a shape of a line crossing the active region 103 and the isolation layer 102. The trenches 105 may be spaced apart from each other in a second direction D2. The first direction D1 may be perpendicular to the second direction D2. The trench 105 may have a shallower depth than the isolation trench 102T. According to another embodiment of the present invention, the lower portion of the trench 105 may have a curvature. The trench 105 may be a space where the buried gate structure 100G is formed. Thus, the trench 105 may be referred to as a ‘gate trench 105’.

The first doped region 110 and the second doped regions 111 may be formed in the active regions 103. The first doped region 110 and the second doped regions 111 may be regions doped with a conductive dopant. For example, the conductive dopant may include phosphorus (P), arsenic (As), antimony (Sb), or boron (B). The first doped region 110 and the second doped regions 111 may be doped with the dopants of the same conductivity type. The first doped region 110 and the second doped regions 111 may be disposed in the active regions 103 on both sides of the trench 105. The first and second doped regions 110 and 111 may be disposed spaced apart from each other by the trench 105. The bottom surfaces of the first doped region 110 and the second doped regions 111 may be disposed at a predetermined depth from the top surface of the active regions 103. The bottom surfaces of the first doped region 110 and the second doped regions 111 may be higher than the bottom surface of the trench 105. The first doped region 110 may be referred to as a ‘first source/drain region 110’, and each second doped region 111 may be referred to as a ‘second source/drain region 111’. A channel may be defined between the first doped region 110 and each second doped region 111 by the buried gate structure 100G. The channel may be defined along the profile of the trench 105.

The trench 105 may include a first trench T1 and a second trench T2. The first trench T1 may be formed in the active region 103. The second trench T2 may be formed in the isolation layer 102. The trench 105 may continuously extend from the first trench T1 to the second trench T2. In the trench 105, the bottom surface of the first trench T1 may be disposed at a higher level than the bottom surface of the second trench T2. The height difference between the first trench T1 and the second trench T2 may be formed as the isolation layer 102 is recessed. Accordingly, the second trench T2 may include a recess region R having a lower bottom surface than the first trench T1. A fin 103F may be formed in the active region 103 due to the height difference between the first trench T1 and the second trench T2. Accordingly, the active region 103 may include the fin 103F.

As described above, the fin 103F may be formed below the first trench T1, and the sidewall of the fin 103F may be exposed by the recessed isolation layer 102F. The fin 103F may be a portion where a portion of the channel (not shown) is formed. The fin 103F may increase the channel width and improve the electrical characteristics.

According to another embodiment of the present invention, the fin 103F may be omitted.

The buried gate structure 100G may be embedded in the trench 105. The buried gate structure 100G may be disposed in the active region 103 between the first doped region 110 and the second doped region 111 and extend into the isolation layer 102. In the buried gate structure 100G, the bottom surface of the portion disposed in the active region 103 and the bottom surface of the portion disposed in the isolation layer 102 may be disposed at different levels. When the fin 103F is omitted, the bottom surface of the portion disposed in the active region 103 and the bottom surface of the portion disposed in the isolation layer 102 may be disposed at the same level in the buried gate structure 100G.

The buried gate structure 100G may include a gate dielectric layer 106 that covers the bottom surface and sidewalls of the trench 105, and a lower buried gate LBG, an upper buried gate UBG, and a capping layer 109 that are sequentially stacked over the gate dielectric layer 106 to fill the trench 105. The lower buried gate LBG may be referred to as a ‘first gate LBG’ or a ‘first buried conductive layer LBG.’ The upper buried gate UBG may be referred to as a ‘second gate UBG’ or a ‘second buried conductive layer UBG.’

The gate dielectric layer 106 may be conformally formed on the bottom and inner surfaces of the trench 105. The gate dielectric layer 106 may include silicon oxide, silicon nitride, silicon oxynitride, a high-k material, or a combination thereof. The high-k material may include materials having a greater dielectric constant than silicon oxide. For example, the high-k material may include materials whose dielectric constant is greater than approximately 3.9. For another example, the high-k material may include materials whose dielectric constant is greater than approximately 10. For yet another example, the high-k material may include materials having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may selectively be used. The gate dielectric layer 106 may include a metal oxide.

The top surface of the lower buried gate LBG may be disposed at a lower level than the bottom surfaces of the first and second doped regions 110 and 111. The lower buried gate LBG may include a stacked structure of the first barrier layer 107 and the first gate electrode 108. The first barrier layer 107 and the first gate electrode 108 may have their top surfaces at the same level. The first gate electrode 108 may be formed over the first barrier layer 107. The first barrier layer 107 may have a liner shape, and the first gate electrode 108 may have a bulk shape. The bottom and outer surfaces of the first gate electrode 108 may be surrounded by the first barrier layer 107.

The first barrier layer 107 may serve to supply oxygen to the first gate electrode 108. The first barrier layer 107 may include a metal-based oxygen material (i.e., material containing oxygen). The first barrier layer 107 may be referred to as an ‘oxygen supply layer 107.’ The first barrier layer 107 may include multiple layers. The first barrier layer 107 may be a multi-layer containing a metal nitride containing oxygen material. The first barrier layer 107 may be a triple layer containing a metal nitride containing oxygen material. The first barrier layer 107 may include a stacked structure of a first metal oxynitride 107A, a metal nitride 107B, and a second metal oxynitride 107C. For example, the first barrier layer 107 may include a stacked structure of a first titanium oxynitride 107A (TiON), a first titanium nitride 107B (TiN), and a second titanium oxynitride 107C (TiON).

According to another embodiment of the present invention, the first barrier layer 107 may include a stacked structure of a first metal nitride 107A, a metal oxynitride 107B, and a second metal nitride 107C. For example, the first barrier layer 107 may include a stacked structure of a first titanium nitride 107A (TiN), titanium oxynitride 107B (TiON), and a second titanium nitride 107C (TiN).

According to yet another embodiment of the present invention, the first barrier layer 107 may be a triple layer containing a metal nitride and a metal oxide. The first barrier layer 107 may include a stacked structure of the first metal nitride 107A, the metal oxide 107B, and the second metal nitride 107C. For example, the first barrier layer 107 may include a stacked structure of the first titanium nitride 107A (TiN), the titanium oxide 107B (TiO), and the second titanium nitride 107C (TiN).

According to yet another embodiment of the present invention, the first barrier layer 107 may include a stacked structure of a metal nitride and a metal oxide. For example, the first barrier layer 107 may include a stacked structure of titanium nitride (TiN) and titanium oxide (TiO).

The first gate electrode 108 may have a high work function. Here, the high work function may refer to a work function that is greater than the mid-gap work function of silicon. A low work function may refer to a work function that is less than the mid-gap work function of silicon. To be specific, the high work function may have a work function which is greater than approximately 4.5 eV, and the low work function may have a work function which is less than approximately 4.5 eV.

According to another embodiment of the present invention, the first gate electrode 108 may have an increased high work function. The first gate electrode 108 may include a metal nitride. The first gate electrode 108 may be referred to as a ‘first conductive layer.’ The first gate electrode 108 may include a metal nitride containing oxygen material. The first gate electrode 108 may include a metal nitride with a controlled oxygen content. For example, the first gate electrode 108 may include a high-oxygen titanium nitride (high-oxygen TiN). Titanium nitride may have a high work function, and the titanium nitride may contain oxygen to further increase the work function of the titanium nitride. The oxygen content of the high-oxygen titanium nitride (high-oxygen TiN) may be greater than the oxygen content of the titanium nitride (TiN). The high-oxygen titanium nitride (high-oxygen TiN) may be formed, as the oxygen in the first barrier layer 107 diffuses into the first gate electrode 108 during a heat treatment. The oxygen content of the high-oxygen titanium nitride (high-oxygen TiN) may be adjusted in a range that the work function may be increased while maintaining the resistance of the first gate electrode 108.

The upper buried gate UBG may be formed over the lower buried gate LBG. The top surface of the upper buried gate UBG may be disposed at a lower level than the top surface of the active region 103 including the first and second doped regions 110 and 111. The upper buried gate UBG may be formed of a low-resistance material to decrease the gate sheet resistance. The upper buried gate UBG may have a low work function. The upper buried gate UBG may include a metal nitride. The upper buried gate UBG may include a metal nitride with a controlled oxygen content. The upper buried gate UBG may include a metal nitride having a lower oxygen content in the film than the first gate electrode 108. For example, the upper buried gate 108 may include a low-oxygen titanium nitride (low-oxygen TiN). Here, the low-oxygen titanium nitride (low-oxygen TiN) may refer to titanium nitride that does not contain oxygen in the film or has a minimal oxygen content. The oxygen content of the low-oxygen titanium nitride (low-oxygen TiN) may be less than the oxygen content of titanium nitride (TiN).

According to this embodiment of the present invention, titanium nitride (TiN) which is compared with the high-oxygen titanium nitride or the low-oxygen titanium nitride may have a ratio of titanium to nitrogen of approximately 1:1, that is, the titanium nitride (TiN) may have a stoichiometric composition. Stoichiometric composition may refer to the state that a compound has an ideal chemical composition ratio. According to this embodiment of the present invention, the titanium nitride (TiN) having a stoichiometric composition may refer to titanium nitride in which the inflow of oxygen is minimized during the fabrication process.

The capping layer 109 may serve to protect the upper buried gate UBG. The capping layer 109 may fill the upper portion of the trench 105 over the upper buried gate UBG. The top surface of the capping layer 109 may be disposed at the same level as the top surface of the hard mask 104. The top surface of the capping layer 109 may be disposed at a higher level than the top surface of the substrate 101. According to another embodiment of the present invention, the top surface of the capping layer 109 may be disposed at the same level as the top surface of the substrate 101.

The capping layer 109 may include a dielectric material. The capping layer 109 may include silicon nitride, silicon oxynitride, or a combination thereof. According to another embodiment of the present invention, the capping layer 109 may include a combination of silicon nitride and silicon oxide. The capping layer 109 may include a silicon nitride liner and a Spin-On-Dielectric (SOD) material.

As described above, according to this embodiment of the present invention, the lower buried gate LBG and the upper buried gate UBG may have a high work function and a low work function by adjusting the oxygen contents of the lower buried gate LBG and the upper buried gate UBG, respectively. Also, this embodiment may decrease the device resistance by forming both of the lower and upper buried gates LBG and UBG of a metal-based material and improve refresh performance, compared to the dual gate structure in which a metal material and a silicon material are stacked.

FIGS. 3 to 13 are cross-sectional views illustrating semiconductor devices 200 to 1200 in accordance with second to 12^{th} embodiments of the present invention. FIGS. 3 to 13 may include the same structure as that of FIG. 2A, except for the buried gate structure. The substrate 101, the isolation layer 102, the active region 103, the hard mask layer 104, the gate dielectric layer 106, the capping layer 109, the first doped region 110, and the second doped region 111 illustrated in FIGS. 3 to 13 may have the same material and structure as those in FIG. 2A, and a detailed description of them will be omitted.

Referring to FIG. 3, the semiconductor device 200 in accordance with the second embodiment of the present invention may include a substrate 101, and a buried gate structure 200G embedded in the substrate 101.

The buried gate structure 200G may include a gate dielectric layer 106 that covers the bottom surface and sidewalls of the trench 105, and a lower buried gate LBG and an upper buried gate UBG that are sequentially stacked over the gate dielectric layer 106 to fill the trench 105.

The top surface of the lower buried gate LBG may be disposed at a lower level than the bottom surfaces of the first and second doped regions 110 and 111. The lower buried gate LBG may include a stacked structure of a first barrier layer 201 and the first gate electrode 108. The first barrier layer 201 and the first gate electrode 108 may have their top surfaces at the same level. The first gate electrode 108 may be formed over the first barrier layer 201. The first barrier layer 201 may have a liner shape, and the first gate electrode 108 may have a bulk shape. The bottom and outer surfaces of the first gate electrode 108 may be surrounded by the first barrier layer 201.

The first barrier layer 201 may serve to supply oxygen to the first gate electrode 108. The first barrier layer 201 may include a metal-based oxygen material. The first barrier layer 201 may be referred to as an ‘oxygen supply layer 201.’ The first barrier layer 201 may be a metal nitride containing oxygen material. The first barrier layer 201 may include a metal oxynitride. For example, the first barrier layer 201 may be titanium oxynitride (TION).

The first gate electrode 108 may have a high work function. Here, the high work function may refer to a work function that is greater than the mid-gap work function of silicon. A low work function may refer to a work function that is less than the mid-gap work function of silicon. To be specific, the high work function may have a work function that is greater than approximately 4.5 eV, and the low work function may have a work function that is less than approximately 4.5 eV.

According to another embodiment of the present invention, the first gate electrode 108 may have an increased high work function. The first gate electrode 108 may include a metal nitride. The first gate electrode 108 may include a metal nitride containing oxygen material. The first gate electrode 108 may include a metal nitride with a controlled oxygen content. For example, the first gate electrode 108 may include a high-oxygen titanium nitride (high-oxygen TiN). Titanium nitride may have a high work function, and oxygen may be contained in the titanium nitride to further increase the work function of the titanium nitride. The oxygen content of the high-oxygen titanium nitride (high-oxygen TiN) may be greater than the oxygen content of titanium nitride (TiN). The high-oxygen titanium nitride (high-oxygen TiN) may be formed, as the oxygen in the first barrier layer 201 diffuses into the first gate electrode 108 during a heat treatment. The oxygen content of the high-oxygen titanium nitride (high-oxygen TiN) may be adjusted in a range that the work function may be increased while maintaining the resistance of the first gate electrode 108.

The upper buried gate UBG may be formed over the lower buried gate LBG. The top surface of the upper buried gate UBG may be disposed at a lower level than the top surface of the active region 103 including the first and second doped regions 110 and 111. The upper buried gate UBG may be formed of a low-resistance material to decrease the gate sheet resistance. The upper buried gate UBG may have a low work function. The upper buried gate UBG may include a metal nitride. The upper buried gate UBG may include a metal nitride with a controlled oxygen content. The upper buried gate UBG may include a metal nitride having a lower oxygen content in the film than the first gate electrode 108. For example, the upper buried gate 108 may include a low-oxygen titanium nitride (low-oxygen TiN). Here, the low-oxygen titanium nitride (low-oxygen TiN) may refer to titanium nitride that does not contain oxygen in the film or has a minimal oxygen content. The oxygen content of the low-oxygen titanium nitride (low-oxygen TiN) may be less than the oxygen content of titanium nitride (TiN).

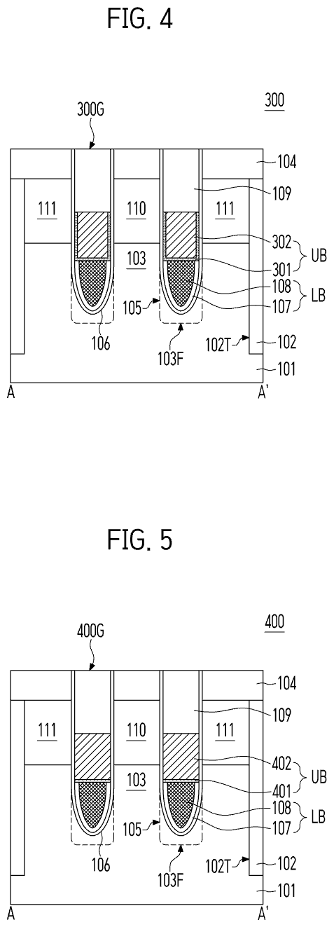

Referring to FIG. 4, the semiconductor device 300 in accordance with the third embodiment of the present invention may include a substrate 101, and a buried gate structure 300G which is embedded in the substrate 101.

The buried gate structure 300G may include a gate dielectric layer 106 that covers the bottom surface and sidewalls of the trench 105, and a lower buried gate LBG and an upper buried gate UBG that are sequentially stacked over the gate dielectric layer 106 to fill the trench 105.

The top surface of the lower buried gate LBG may be disposed at a lower level than the bottom surfaces of the first and second doped regions 110 and 111. The lower buried gate LBG may include a stacked structure of the first barrier layer 107 and the first gate electrode 108. The first barrier layer 107 and the first gate electrode 108 may have their top surfaces at the same level. The first gate electrode 108 may be formed over the first barrier layer 107. The first barrier layer 107 may have a liner shape, and the first gate electrode 108 may have a bulk shape. The bottom and outer surfaces of the first gate electrode 108 may be surrounded by the first barrier layer 107.

The first barrier layer 107 may serve to supply oxygen to the first gate electrode 108. The first barrier layer 107 may include a metal-based oxygen material. The first barrier layer 107 may be referred to as an ‘oxygen supply layer 107.’ The first barrier layer 107 may include multiple layers. The first barrier layer 107 may be a multi-layer containing a metal nitride containing oxygen material. The first barrier layer 107 may be a triple layer containing a metal nitride containing oxygen material. The first barrier layer 107 may include a stacked structure of a first metal oxynitride 107A, a metal nitride 107B, and a second metal oxynitride 107C, as shown in FIG. 2A. For example, the first barrier layer 107 may include a stacked structure of a first titanium oxynitride 107A (TiON), a first titanium nitride 107B (TiN), and a second titanium oxynitride 107C (TiON).

According to another embodiment of the present invention, the first barrier layer 107 may include a stacked structure of the first metal nitride 107A, the metal oxynitride 107B, and the second metal nitride 107C, as shown in FIG. 2A. For example, the first barrier layer 107 may include a stacked structure of the first titanium nitride 107A (TiN), the titanium oxynitride 107B (TiON), and the second titanium nitride 107C (TiN).

According to yet another embodiment of the present invention, the first barrier layer 107 may be a triple layer including a metal nitride and a metal oxide. The first barrier layer 107 may include a stacked structure of the first metal nitride 107A, the metal oxide 107B, and the second metal nitride 107C, as shown in FIG. 2A. For example, the first barrier layer 107 may include a stacked structure of the first titanium nitride 107A (TiN), the titanium oxide 107B (TiO), and the second titanium nitride 107C (TiN).

According to yet another embodiment of the present invention, the first barrier layer 107 may include a stacked structure of a metal nitride and a metal oxide. For example, the first barrier layer 107 may include a stacked structure of titanium nitride (TiN) and titanium oxide (TiO).

According to another embodiment of the present invention, the first barrier layer 107 may be a single layer of a metal nitride containing oxygen material, as illustrated in FIG. 3. For example, the first barrier layer 107 may be a single layer of titanium oxynitride (TiON).

The first gate electrode 108 may have a high work function. Here, the high work function may refer to a work function that is greater than the mid-gap work function of silicon. A low work function may refer to a work function that is less than the mid-gap work function of silicon. To be specific, the high work function may have a work function that is greater than approximately 4.5 eV, and the low work function may have a work function that is less than approximately 4.5 eV.

According to another embodiment of the present invention, the first gate electrode 108 may have an increased high work function. The first gate electrode 108 may include a metal nitride. The first gate electrode 108 may include a metal nitride containing oxygen material. The first gate electrode 108 may include a metal nitride with a controlled oxygen content. For example, the first gate electrode 108 may include a high-oxygen titanium nitride (high-oxygen TiN). Titanium nitride may have a high work function, and oxygen may be contained in the titanium nitride to further increase the work function of the titanium nitride. The oxygen content of the high-oxygen titanium nitride (high-oxygen TiN) may be greater than the oxygen content of the titanium nitride (TN). The high-oxygen titanium nitride (high-oxygen TiN) may be formed, as the oxygen in the first barrier layer 201 diffuses into the first gate electrode 108 during a heat treatment. The oxygen content of the high-oxygen titanium nitride may be adjusted in a range that the work function may be increased while maintaining the resistance of the first gate electrode 108.

The upper buried gate UBG may be formed over the lower buried gate LBG. The top surface of the upper buried gate UBG may be disposed at a lower level than the top surface of the active region 103 including the first and second doped regions 110 and 111. The upper buried gate UBG may have a stacked structure of a second barrier layer 301 and a second gate electrode 302. The second barrier layer 301 and the second gate electrode 302 may have their top surfaces at the same level. The second gate electrode 302 may be formed over the second barrier layer 301. The second barrier layer 301 may have a liner shape, and the second gate electrode 302 may have a bulk shape. The bottom and outer surfaces of the second gate electrode 302 may be surrounded by the second barrier layer 301.

The second barrier layer 301 may be disposed between the first gate electrode 108 and the second gate electrode 302, and between the second gate electrode 302 and the gate dielectric layer 106. The second barrier layer 301 may serve as a barrier that separates the first gate electrode 108 and the second gate electrode 302 from each other and prevent the migration of oxygen or metal ions between them. Also, the second barrier layer 301 may serve to capture oxygen on the surface of the first gate electrode 108. The second barrier layer 301 may be referred to as a ‘oxygen capturing layer 301.’ The second barrier layer 301 may capture the oxygen on the surface of the first gate electrode 108 and prevent the oxygen on the surface of the first gate electrode 108 from diffusing into the second gate electrode 302. The second barrier layer 301 may also be referred to as an ‘oxygen diffusion prevention layer 301.’ The second barrier layer 301 may be formed in-situ or ex-situ with the second gate electrode 302. The second barrier layer 301 may include a silicon-based material. For example, the second barrier layer 301 may include polysilicon. The second barrier layer 301 may be adjusted to have a minimal thickness capable of capturing oxygen without increasing the device resistance. For example, the second barrier layer 301 may be formed to have a thickness of approximately 2 nm or less.

The second gate electrode 302 may be formed of a low-resistance material to decrease the gate sheet resistance. The second gate electrode 302 may have a low work function. The second gate electrode 302 may include a metal nitride. The second gate electrode may be referred to as a ‘second conductive layer.’ The second gate electrode 302 may include a metal nitride with a controlled oxygen content. The second gate electrode 302 may include a metal nitride having less oxygen content in the film than the first gate electrode 108. For example, the second gate electrode 302 may include a low-oxygen titanium nitride (low-oxygen TiN). Here, the low-oxygen titanium nitride may refer to titanium nitride that does not contain oxygen in the film or has a minimal oxygen content. The oxygen content of the low-oxygen titanium nitride (low-oxygen TiN) may be less than the oxygen content of the titanium nitride (TiN).

Referring to FIG. 5, the semiconductor device 400 in accordance with the fourth embodiment of the present invention may include a substrate 101, and a buried gate structure 400G embedded in the substrate 101.

The buried gate structure 400G may include a gate dielectric layer 106 that covers the bottom surface and sidewalls of the trench 105, and a lower buried gate LBG and an upper buried gate UBG that are sequentially stacked over the gate dielectric layer 106 to fill the trench 105.

The top surface of the lower buried gate LBG may be disposed at a lower level than the bottom surfaces of the first and second doped regions 110 and 111. The lower buried gate LBG may include a stacked structure of the first barrier layer 107 and the first gate electrode 108. The first barrier layer 107 and the first gate electrode 108 may have their top surfaces at the same level. The first gate electrode 108 may be formed over the first barrier layer 107. The first barrier layer 107 may have a liner shape, and the first gate electrode 108 may have a bulk shape. The bottom and outer surfaces of the first gate electrode 108 may be surrounded by the first barrier layer 107.

The first barrier layer 107 may serve to supply oxygen to the first gate electrode 108. The first barrier layer 107 may include a metal-based oxygen material. The first barrier layer 107 may be referred to as an ‘oxygen supply layer 107.’ The first barrier layer 107 may include multiple layers. The first barrier layer 107 may be a multi-layer containing a metal nitride containing oxygen material. The first barrier layer 107 may be a triple layer containing a metal nitride containing oxygen material. The first barrier layer 107 may include a stacked structure of the first metal oxynitride 107A, the metal nitride 107B, and the second metal oxynitride 107C, as shown in FIG. 2A. For example, the first barrier layer 107 may include a stacked structure of the first titanium oxynitride 107A (TiON), the first titanium nitride 107B (TiN), and the second titanium oxynitride 107C (TiON).

According to another embodiment of the present invention, the first barrier layer 107 may include a stacked structure of the first metal nitride 107A, the metal oxynitride 107B, and the second metal nitride 107C, as shown in FIG. 2A. For example, the first barrier layer 107 may include a stacked structure of the first titanium nitride 107A (TiN), the titanium oxynitride 107B (TiON), and the second titanium nitride 107C (TiN).

According to yet another embodiment of the present invention, the first barrier layer 107 may be a triple layer including a metal nitride and a metal oxide. The first barrier layer 107 may include a stacked structure of the first metal nitride 107A, the metal oxide 107B, and the second metal nitride 107C, as shown in FIG. 2A. For example, the first barrier layer 107 may include a stacked structure of the first titanium nitride 107A (TiN), the titanium oxide 107B (TiO), and the second titanium nitride 107C (TiN).

According to yet another embodiment of the present invention, the first barrier layer 107 may include a stacked structure of a metal nitride and a metal oxide. For example, the first barrier layer 107 may include a stacked structure of titanium nitride (TiN) and titanium oxide (TiO).

According to another embodiment of the present invention, the first barrier layer 107 may be a single layer of a metal nitride containing oxygen material, as illustrated in FIG. 3. For example, the first barrier layer 107 may be a single layer of titanium oxynitride (TiON).

The first gate electrode 108 may have a high work function. Here, the high work function may refer to a work function that is greater than the mid-gap work function of silicon. A low work function may refer to a work function that is less than the mid-gap work function of silicon. To be specific, the high work function may have a work function which is greater than approximately 4.5 eV, and the low work function may have a work function which is less than approximately 4.5 eV.

According to another embodiment of the present invention, the first gate electrode 108 may have an increased high work function. The first gate electrode 108 may include a metal nitride. The first gate electrode 108 may include a metal nitride containing oxygen material. The first gate electrode 108 may include a metal nitride with a controlled oxygen content. For example, the first gate electrode 108 may include a high-oxygen titanium nitride (high-oxygen TiN). Titanium nitride may have a high work function, and oxygen may be contained in the titanium nitride to further increase the work function of the titanium nitride. The oxygen content of the high-oxygen titanium nitride (high-oxygen TiN) may be greater than the oxygen content of the titanium nitride (TiN). The high-oxygen titanium nitride (high-oxygen TiN) may be formed, as the oxygen in the first barrier layer 201 diffuses into the first gate electrode 108 during a heat treatment. The oxygen content of the high-oxygen titanium nitride (high-oxygen TiN) may be adjusted in a range that the work function may be increased while maintaining the resistance of the first gate electrode 108.

The upper buried gate UBG may be formed over the lower buried gate LBG. The top surface of the upper buried gate UBG may be disposed at a lower level than the top surface of the active region 103 including the first and second doped regions 110 and 111. The upper buried gate UBG may have a stacked structure of the second barrier layer 401 and the second gate electrode 402. The second gate electrode 402 may be formed over the second barrier layer 401.

The second barrier layer 401 may be disposed between the first gate electrode 108 and the second gate electrode 402. The second barrier layer 401 may serve as a barrier that separates the first gate electrode 108 and the second gate electrode 402 from each other and prevent the migration of oxygen or metal ions between them. Also, the second barrier layer 401 may capture the oxygen on the surface of the first gate electrode 108. The second barrier layer 401 may be referred to as an ‘oxygen capturing layer 401.’ The second barrier layer 401 may capture the oxygen on the surface of the first gate electrode 108 and prevent the oxygen on the surface of the first gate electrode 108 from diffusing into the second gate electrode 402. The second barrier layer 401 may also be referred to as an ‘oxygen diffusion prevention layer 401.’ The second barrier layer 401 may be formed in-situ or ex-situ with the second gate electrode 402. The second barrier layer 401 may include a silicon-based material. For example, the second barrier layer 401 may include polysilicon. The second barrier layer 401 may be adjusted to have a minimal thickness capable of capturing oxygen without increasing the device resistance. For example, the second barrier layer 401 may be formed to have a thickness of approximately 2 nm or less.

The second gate electrode 402 may be formed of a low-resistance material to decrease the gate sheet resistance. The second gate electrode 402 may have a low work function. The second gate electrode 402 may include a metal nitride. The second gate electrode 402 may include a metal nitride with a controlled oxygen content. The second gate electrode 402 may include a metal nitride having less oxygen content in the film than the first gate electrode 108. For example, the second gate electrode 402 may include a low-oxygen titanium nitride (low-oxygen TiN). Here, the low-oxygen titanium nitride may refer to titanium nitride that does not contain oxygen in the film or has a minimal oxygen content. The oxygen content of the low-oxygen titanium nitride (low-oxygen TiN) may be less than the oxygen content of the titanium nitride (TiN).

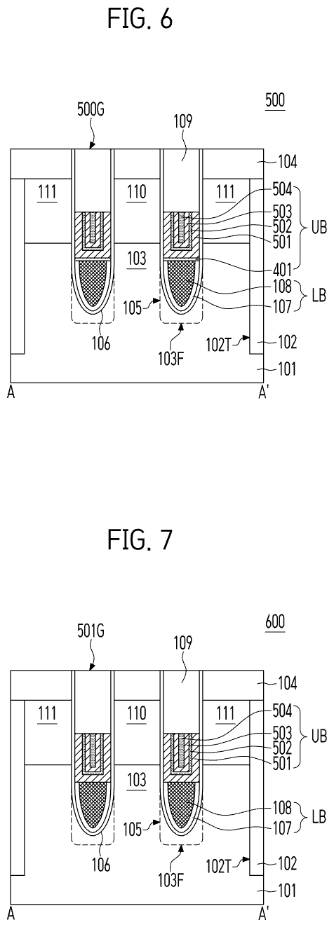

Referring to FIG. 6, the semiconductor device 500 in accordance with the fifth embodiment of the present invention may include a substrate 101, and a buried gate structure 500G embedded in the substrate 101.

The buried gate structure 500G may include a gate dielectric layer 106 that covers the bottom surface and sidewalls of the trench 105, and a lower buried gate LBG and an upper buried gate UBG that are sequentially stacked over the gate dielectric layer 106 to fill the trench 105.

The top surface of the lower buried gate LBG may be disposed at a lower level than the bottom surfaces of the first and second doped regions 110 and 111. The lower buried gate LBG may include a stacked structure of the first barrier layer 107 and the first gate electrode 108. The first barrier layer 107 and the first gate electrode 108 may have their top surfaces at the same level. The first gate electrode 108 may be formed over the first barrier layer 107. The first barrier layer 107 may have a liner shape, and the first gate electrode 108 may have a bulk shape. The bottom and outer surfaces of the first gate electrode 108 may be surrounded by the first barrier layer 107.

The first barrier layer 107 may serve to supply oxygen to the first gate electrode 108. The first barrier layer 107 may include a metal-based oxygen material. The first barrier layer 107 may be referred to as an ‘oxygen supply layer 107.’ The first barrier layer 107 may include multiple layers. The first barrier layer 107 may be a multi-layer containing a metal nitride containing oxygen material. The first barrier layer 107 may be a triple layer containing a metal nitride containing oxygen material. The first barrier layer 107 may include a stacked structure of the first metal oxynitride 107A, the metal nitride 107B, and the second metal oxynitride 107C, as shown in FIG. 2A. For example, the first barrier layer 107 may include a stacked structure of the first titanium oxynitride 107A (TiON), the first titanium nitride 107B (TiN), and the second titanium oxynitride 107C (TiON).

According to another embodiment of the present invention, the first barrier layer 107 may include a stacked structure of the first metal nitride 107A, the metal oxynitride 107B, and the second metal nitride 107C, as shown in FIG. 2A. For example, the first barrier layer 107 may include a stacked structure of the first titanium nitride 107A (TiN), the titanium oxynitride 107B (TiON), and the second titanium nitride 107C (TiN).

According to yet another embodiment of the present invention, the first barrier layer 107 may be a triple layer containing a metal nitride and a metal oxide. The first barrier layer 107 may include a stacked structure of the first metal nitride 107A, the metal oxide 107B, and the second metal nitride 107C, as shown in FIG. 2A. For example, the first barrier layer 107 may include a stacked structure of the first titanium nitride 107A (TiN), the titanium oxide 107B (TiO), and the second titanium nitride 107C (TiN).

According to yet another embodiment of the present invention, the first barrier layer 107 may include a stacked structure of a metal nitride and a metal oxide. For example, the first barrier layer 107 may include a stacked structure of titanium nitride (TiN) or titanium oxide (TiO).

According to another embodiment of the present invention, the first barrier layer 107 may be a single layer of a metal nitride containing oxygen material, as illustrated in FIG. 3. For example, the first barrier layer 107 may be a single layer of titanium oxynitride (TiON).

The first gate electrode 108 may have a high work function. Here, the high work function may refer to a work function that is greater than the mid-gap work function of silicon. A low work function may refer to a work function that is less than the mid-gap work function of silicon. To be specific, the high work function may have a work function which is greater than approximately 4.5 eV, and the low work function may have a work function which is less than approximately 4.5 eV.

According to another embodiment of the present invention, the first gate electrode 108 may have an increased high work function. The first gate electrode 108 may include a metal nitride. The first gate electrode 108 may include a metal nitride containing oxygen material. The first gate electrode 108 may include a metal nitride with a controlled oxygen content. For example, the first gate electrode 108 may include a high-oxygen titanium nitride (high-oxygen TiN). Titanium nitride may have a high work function, and oxygen may be contained in the titanium nitride to further increase the work function of the titanium nitride. The oxygen content of the high-oxygen titanium nitride (high-oxygen TiN) may be greater than the oxygen content of titanium nitride (TiN). The high-oxygen titanium nitride (high-oxygen TiN) may be formed, as the oxygen in the first barrier layer 201 diffuses into the first gate electrode 108 during a heat treatment. The oxygen content of the high-oxygen titanium nitride (high-oxygen TiN) may be adjusted in a range that the work function may be increased while maintaining the resistance of the first gate electrode 108.

The upper buried gate UBG may be formed over the lower buried gate LBG. The top surface of the upper buried gate UBG may be disposed at a lower level than the top surface of the active region 103 including the first and second doped regions 110 and 111. The upper buried gate UBG may have a stacked structure of the second barrier layer 401, a second gate electrode 501, a first oxygen capturing layer 502, a third gate electrode 503, and a second oxygen capturing layer 504.

The second barrier layer 401 may be disposed between the first gate electrode 108 and the second gate electrode 501. The second barrier layer 401 may serve as a barrier that separates the first gate electrode 108 and the second gate electrode 501 from each other and may prevent the migration of oxygen or metal ions between them. Also, the second barrier layer 401 may capture the oxygen on the surface of the first gate electrode 108. The second barrier layer 401 may be referred to as an ‘oxygen capturing layer 401.’ The second barrier layer 401 may capture the oxygen on the surface of the first gate electrode 108 and prevent the oxygen on the surface of the first gate electrode 108 from diffusing into the second gate electrode 501 and the third gate electrode 503. The second barrier layer 401 may also be referred to as an ‘oxygen diffusion prevention layer 401.’ The second barrier layer 401 may be formed in-situ or ex-situ with the second gate electrode 501. The second barrier layer 401 may include a silicon-based material. For example, the second barrier layer 401 may include polysilicon. The second barrier layer 401 may be adjusted to have a minimal thickness capable of capturing oxygen without increasing the device resistance. For example, the second barrier layer 401 may be formed to have a thickness of approximately 2 nm or less.

The second gate electrode 501, the first oxygen capturing layer 502, and the third gate electrode 503 may have a cylinder shape. The second gate electrode 501 may cover the outer surface of the first oxygen capturing layer 502. The first oxygen capturing layer 502 may cover the outer surface of the third gate electrode 503. The third gate electrode 503 may cover the outer surface of the second oxygen capturing layer 504. The top surfaces of the second gate electrode 501, the first oxygen capturing layer 502, the third gate electrode 503, and the second oxygen capturing layer 504 may be disposed at the same level.

The first and second oxygen capturing layers 502 and 504 may capture the oxygen in the second and third gate electrodes 501 and 503. Each of the first and second oxygen capturing layers 502 and 504 may include a silicon material. Each of the first and second oxygen capturing layers 502 and 504 may include polysilicon. The first and second oxygen capturing layers 502 and 504 may be adjusted to have a thickness that does not increase the device resistance. Each of the first and second oxygen capturing layers 502 and 504 may be adjusted to have a thickness that does not exceed approximately 15 Å. That is, each of the first and second oxygen capturing layers 502 and 504 may be formed to have a thickness of approximately 15 Å or less.

The second gate electrode 501 and the third gate electrode 503 may be formed of a low-resistance material to decrease the gate sheet resistance. Each of the second gate electrode 501 and the third gate electrode 503 may have a low work function. The second and third gate electrodes 501 and 503 may be referred to as ‘second and third conductive layers.’ Each of the second gate electrode 501 and the third gate electrode 503 may include a metal nitride. Each of the second gate electrode 501 and the third gate electrode 503 may include a metal nitride with a controlled oxygen content. Each of the second gate electrode 501 and the third gate electrode 503 may include a metal nitride having less oxygen content in the film than the first gate electrode 108. For example, each of the second gate electrode 501 and the third gate electrode 503 may include a low-oxygen titanium nitride (low-oxygen TiN). Here, the low-oxygen titanium nitride may refer to titanium nitride that does not contain oxygen in the film or has a minimal oxygen content. The oxygen content of the low-oxygen titanium nitride (low-oxygen TiN) may be less than the oxygen content of titanium nitride (TiN). The second gate electrode 501 may be formed to be approximately 50 Å or less. According to another embodiment of the present invention, the third gate electrode 503 may include a low-resistance metal material, such as tungsten (W) or molybdenum (Mo).

Referring to FIG. 7, the semiconductor device 600 in accordance with the sixth embodiment of the present invention may include a substrate 101, and a buried gate structure 501G embedded in the substrate 101.

The buried gate structure 501G may include the same lower buried gate LBG as the buried gate structure 100G illustrated in FIG. 2A. According to another embodiment of the present invention, the buried gate structure 501G may include the same lower buried gate LBG as the buried gate structure 200G illustrated in FIG. 3.

The upper buried gate UBG of the buried gate structure 501G may include a stacked structure of the second gate electrode 501, the first oxygen capturing layer 502, the third gate electrode 503, and the second oxygen capturing layer 504. The second gate electrode 501, the first oxygen capturing layer 502, the third gate electrode 503, and the second oxygen capturing layer 504 may have the same structure except the buried gate structure 500G and the second barrier layer 401 illustrated in FIG. 6.

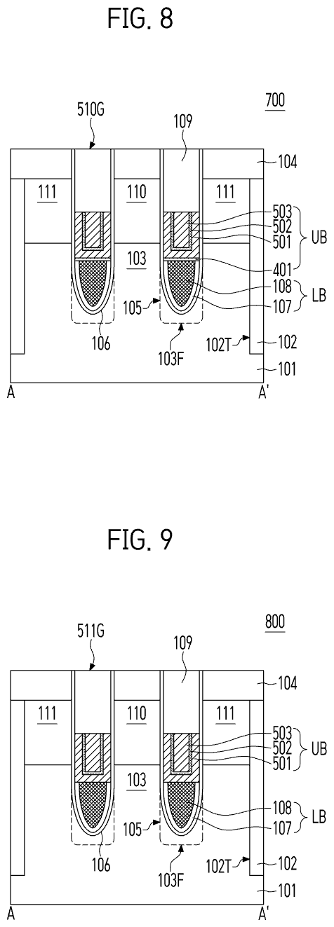

Referring to FIG. 8, the semiconductor device 700 in accordance with the seventh embodiment of the present invention may include a substrate 101, and a buried gate structure 510G embedded in the substrate 101.

The buried gate structure 510G may include the same lower buried gate LBG as the buried gate structure 100G illustrated in FIG. 2A. According to another embodiment of the present invention, the buried gate structure 510G may include the same lower buried gate LBG as the buried gate structure 200G illustrated in FIG. 3.

The upper buried gate UBG of the buried gate structure 510G may include a stacked structure of the second barrier layer 401, the second gate electrode 501, the first oxygen capturing layer 502, and the third gate electrode 503.

The second barrier layer 401 may be disposed between the first gate electrode 108 and the second gate electrode 501. The second barrier layer 401 may serve as a barrier that separates the first gate electrode 108 and the second gate electrode 501 from each other and prevent the migration of oxygen or metal ions between them. Also, the second barrier layer 401 may capture oxygen on the surface of the first gate electrode 108. The second barrier layer 401 may be referred to as an ‘oxygen capturing layer 401.’ The second barrier layer 401 may capture the oxygen on the surface of the first gate electrode 108 and prevent the oxygen on the surface of the first gate electrode 108 from diffusing into the second gate electrode 501 and the third gate electrode 503. The second barrier layer 401 may also be referred to as an ‘oxygen diffusion prevention layer 401.’ The second barrier layer 401 may be formed in-situ or ex-situ with the second gate electrode 501. The second barrier layer 401 may include a silicon-based material. For example, the second barrier layer 401 may include polysilicon. The second barrier layer 401 may be adjusted to have a minimal thickness capable of capturing oxygen without increasing the device resistance. For example, the second barrier layer 401 may be formed to have a thickness of approximately 2 nm or less.

The second gate electrode 501 and the first oxygen capturing layer 502 may have a cylinder shape. The second gate electrode 501 may cover the outer surface of the first oxygen capturing layer 502. The first oxygen capturing layer 502 may cover the outer surface of the third gate electrode 503. The top surfaces of the second gate electrode 501, the first oxygen capturing layer 502, and the third gate electrode 503 may be disposed at the same level.

The first oxygen capturing layer 502 may capture the oxygen in the second and third gate electrodes 501 and 503. The first oxygen capturing layer 502 may include a silicon material. The first oxygen capturing layer 502 may include polysilicon. The first oxygen capturing layer 502 may be adjusted to have a thickness that does not increase the device resistance. The first oxygen capturing layer 502 may be adjusted to have a thickness that does not exceed approximately 15 Å. That is, the first oxygen capturing layer 502 may be formed to have a thickness of approximately 15 Å or less.

The second gate electrode 501 and the third gate electrode 503 may be formed of a low-resistance material to decrease the gate sheet resistance. Each of the second gate electrode 501 and the third gate electrode 503 may have a low work function. Each of the second gate electrode 501 and the third gate electrode 503 may include a metal nitride. Each of the second gate electrode 501 and the third gate electrode 503 may include a metal nitride with a controlled oxygen content. Each of the second gate electrode 501 and the third gate electrode 503 may include a metal nitride having less oxygen content in the film than the first gate electrode 108. For example, each of the second gate electrode 501 and the third gate electrode 503 may include a low-oxygen titanium nitride (low-oxygen TiN). Here, the low-oxygen titanium nitride may refer to titanium nitride that does not contain oxygen in the film or has a minimal oxygen content. The oxygen content of the low-oxygen titanium nitride (low-oxygen TiN) may be less than the oxygen content of titanium nitride (TiN). The second gate electrode 501 may be formed to have a thickness of approximately 50 Å or less.

According to another embodiment of the present invention, the third gate electrode 503 may include a metal material. For example, the third gate electrode 503 may include a low-resistance metal material, such as tungsten (W) or molybdenum (Mo).

Referring to FIG. 9, the semiconductor device 800 in accordance with the eighth embodiment of the present invention may include a substrate 101, and a buried gate structure 511G embedded in the substrate 101.

The buried gate structure 511G may include the same lower buried gate LBG as the buried gate structure 100G illustrated in FIG. 2A. According to another embodiment of the present invention, the buried gate structure 511G may include the same lower buried gate LBG as the buried gate structure 200G illustrated in FIG. 3.

The upper buried gate UBG of the buried gate structure 511G may include a stacked structure of the second gate electrode 501, the first oxygen capturing layer 502, and the third gate electrode 503. The second gate electrode 501, the first oxygen capturing layer 502, and the third gate electrode 503 may have the same structure except for the buried gate structure 510G and the second barrier layer 401 illustrated in FIG. 8.

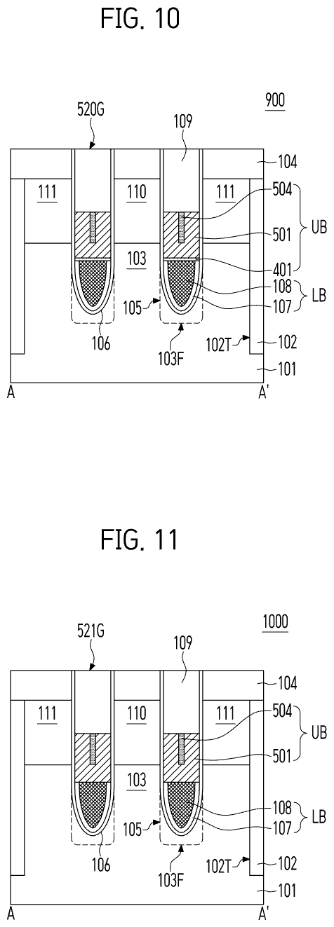

Referring to FIG. 10, the semiconductor device 900 in accordance with the ninth embodiment of the present invention may include a substrate 101, and a buried gate structure 520G embedded in the substrate 101.

The buried gate structure 520G may include the same lower buried gate LBG as the buried gate structure 100G illustrated in FIG. 2A. According to another embodiment of the present invention, the buried gate structure 520G may include the same lower buried gate LBG as the buried gate structure 200G illustrated in FIG. 3.

The upper buried gate UBG of the buried gate structure 520G may include a stacked structure of the second barrier layer 401, the second gate electrode 501, and the first oxygen capturing layer 504.

The second barrier layer 401 may be disposed between the first gate electrode 108 and the second gate electrode 501. The second barrier layer 401 may serve as a barrier that separates the first gate electrode 108 and the second gate electrode 501 from each other and prevent the migration of oxygen or metal ions between them. Also, the second barrier layer 401 may capture the oxygen on the surface of the first gate electrode 108. The second barrier layer 401 may be referred to as an ‘oxygen capturing layer 401.’ The second barrier layer 401 may capture the oxygen on the surface of the first gate electrode 108 and prevent the oxygen on the surface of the first gate electrode 108 from diffusing into the second gate electrode 501 and the third gate electrode 503. The second barrier layer 401 may also be referred to as an ‘oxygen diffusion prevention layer 401.’ The second barrier layer 401 may be formed in-situ or ex-situ with the second gate electrode 501. The second barrier layer 401 may include a silicon-based material. For example, the second barrier layer 401 may include polysilicon. The second barrier layer 401 may be adjusted to have a minimal thickness capable of capturing oxygen without increasing the device resistance. For example, the second barrier layer 401 may be formed to have a thickness of approximately 2 nm or less.

The outer surface of the first oxygen capturing layer 504 may be covered by the second gate electrode 501. The top surfaces of the second gate electrode 501 and the first oxygen capturing layer 504 may be disposed at the same level.

The first oxygen capturing layer 504 may capture the oxygen in the second gate electrode 501. The first oxygen capturing layer 504 may include a silicon material. The first oxygen capturing layer 504 may include polysilicon. The first oxygen capturing layer 504 may be adjusted to have a thickness that does not increase the device resistance. The first oxygen capturing layer 504 may be adjusted to have a thickness that does not exceed approximately 15 Å. That is, the first oxygen capturing layer 504 may be formed to have a thickness of approximately 15 Å or less.

The second gate electrode 501 may be formed of a low-resistance material to decrease the gate sheet resistance. The second gate electrode 501 may have a low work function. The second gate electrode 501 may include a metal nitride. The second gate electrode 501 may include a metal nitride with a controlled oxygen content. The second gate electrode 501 may include a metal nitride having less oxygen content in the film than the first gate electrode 108. For example, the second gate electrode 501 may include a low-oxygen titanium nitride (low-oxygen TiN). Here, the low-oxygen titanium nitride may refer to titanium nitride that does not contain oxygen in the film or has a minimal oxygen content. The oxygen content of the low-oxygen titanium nitride (low-oxygen TiN) may be lower than the oxygen content of titanium nitride (TiN).

Referring to FIG. 11, the semiconductor device 1000 in accordance with the 10^{th} embodiment of the present invention may include a substrate 101, and a buried gate structure 521G embedded in the substrate 101.

The buried gate structure 521G may include the same lower buried gate LBG as the buried gate structure 100G illustrated in FIG. 2A. According to another embodiment of the present invention, the buried gate structure 521G may include the same lower buried gate LBG as the buried gate structure 200G illustrated in FIG. 3.

The upper buried gate UBG of the buried gate structure 521G may include a stacked structure of the second gate electrode 501 and the first oxygen capturing layer 504. The second gate electrode 501 and the first oxygen capturing layer 504 may include the same structure except for the buried gate structure 520G and the second barrier layer 401 illustrated in FIG. 10.

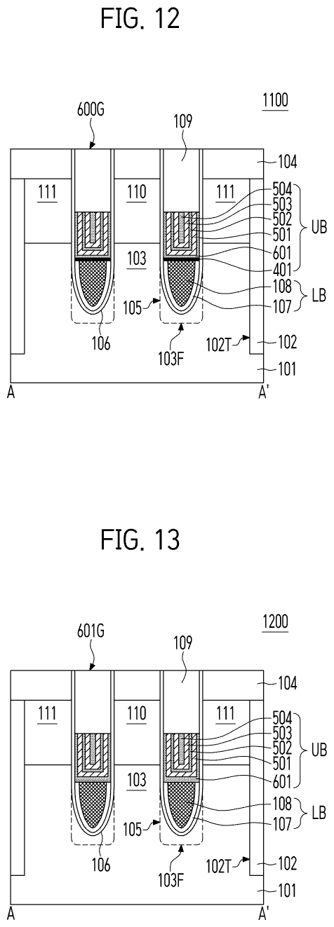

Referring to FIG. 12, the semiconductor device 1100 in accordance with the 11^{th} embodiment of the present invention may include a substrate 101, and a buried gate structure 600G embedded in the substrate 101.

The buried gate structure 600G may include the same lower buried gate LBG as the buried gate structure 100G illustrated in FIG. 2A. According to another embodiment of the present invention, the buried gate structure 600G may include the same lower buried gate LBG as the buried gate structure 200G illustrated in FIG. 3.

The upper buried gate UBG of the buried gate structure 600G may be formed over the lower buried gate LBG. The top surface of the upper buried gate UBG may be disposed at a lower level than the top surface of the active region 103 including the first and second doped regions 110 and 111. The upper buried gate UBG may include a stacked structure of a second barrier layer 401, a second gate dielectric layer 601, a second gate electrode 501, a first oxygen capturing layer 502, a third gate electrode 503, and a second oxygen capturing layer 504.

The buried gate structure 600G may be the same as the buried gate structure 500G illustrated in FIG. 6, except for the second gate dielectric layer 601.

The second barrier layer 401 may be disposed between the first gate electrode 108 and the second gate electrode 501. The second barrier layer 401 may serve as a barrier that separates the first gate electrode 108 and the second gate electrode 501 from each other and prevent the migration of oxygen or metal ions between them. Also, the second barrier layer 401 may capture the oxygen on the surface of the first gate electrode 108. The second barrier layer 401 may be referred to as an ‘oxygen capturing layer 401.’ The second barrier layer 401 may capture the oxygen on the surface of the first gate electrode 108 and prevent the oxygen on the surface of the first gate electrode 108 from diffusing into the second gate electrode 501 and the third gate electrode 503. The second barrier layer 401 may also be referred to as an ‘oxygen diffusion prevention layer 401.’ The second barrier layer 401 may include a silicon-based material. For example, the second barrier layer 401 may include polysilicon. The second barrier layer 401 may be adjusted to have a minimal thickness capable of capturing oxygen without increasing the device resistance. For example, the second barrier layer 401 may be formed to have a thickness of approximately 2 nm or less. The second gate dielectric layer 601 may be disposed between the second barrier layer 401 and the second gate electrode 501, and between the second gate electrode 501 and the gate dielectric layer 106. The second gate dielectric layer 601 may include silicon oxide. The second gate dielectric layer 601 may increase the total thickness of the gate dielectric layer overlapping with the first and second doped regions 110 and 111, thereby reducing the leakage current and GIDL of the sidewall. The thickness of the second gate dielectric layer 601 may be adjusted to have a thickness of at least approximately 50 Å or less.

The second gate electrode 501, the first oxygen capturing layer 502, and the third gate electrode 503 may have a cylinder shape. The second gate electrode 501 may cover the outer surface of the first oxygen capturing layer 502. The first oxygen capturing layer 502 may cover the outer surface of the third gate electrode 503. The third gate electrode 503 may cover the outer surface of the second oxygen capturing layer 504. The top surfaces of the second gate electrode 501, the first oxygen capturing layer 502, the third gate electrode 503, and the second oxygen capturing layer 504 may be disposed at the same level.

The first and second oxygen capturing layers 502 and 504 may capture the oxygen in the second and third gate electrodes 501 and 503. Each of the first and second oxygen capturing layers 502 and 504 may include a silicon material. Each of the first and second oxygen capturing layers 502 and 504 may include polysilicon. The first and second oxygen capturing layers 502 and 504 may be adjusted to have a thickness that does not increase the device resistance. Each of the first and second oxygen capturing layers 502 and 504 may be adjusted to have a thickness that does not exceed approximately 15 Å. That is, each of the first and second oxygen capturing layers 502 and 504 may be formed to have a thickness of approximately 15 Å or less.

The second gate electrode 501 and the third gate electrode 503 may be formed of a low-resistance material to decrease the gate sheet resistance. Each of the second gate electrode 501 and the third gate electrode 503 may have a low work function. Each of the second gate electrode 501 and the third gate electrode 503 may include a metal nitride. Each of the second gate electrode 501 and the third gate electrode 503 may include a metal nitride with a controlled oxygen content. Each of the second gate electrode 501 and the third gate electrode 503 may include a metal nitride having a lower oxygen content in the film than the first gate electrode 108. For example, each of the second gate electrode 501 and the third gate electrode 503 may include a low-oxygen titanium nitride (low-oxygen TiN). Here, the low-oxygen titanium nitride may refer to titanium nitride that does not contain oxygen in the film or has a minimal oxygen content. The oxygen content of the low-oxygen titanium nitride (low-oxygen TiN) may be less than the oxygen content of titanium nitride (TiN). The second gate electrode 501 may be formed to be approximately 50 Å or less. According to another embodiment of the present invention, the third gate electrode 503 may include a low-resistance metal material, such as tungsten (W) or molybdenum (Mo).

Referring to FIG. 13, the semiconductor device 1200 in accordance with the 12^{th} embodiment of the present invention may include a substrate 101, and a buried gate structure 601G embedded in the substrate 101.

The buried gate structure 601G may include the same lower buried gate LBG as the buried gate structure 100G illustrated in FIG. 2A. According to another embodiment of the present invention, the buried gate structure 601G may include the same lower buried gate LBG as the buried gate structure 200G illustrated in FIG. 3.

The upper buried gate UBG of the buried gate structure 601G may include a stacked structure of the second gate dielectric layer 601, the second gate electrode 501, the first oxygen capturing layer 502, the third gate electrode 503, and the second oxygen capturing layer 504. The second gate dielectric layer 601, the second gate electrode 501, the first oxygen capturing layer 502, the third gate electrode 503, and the second oxygen capturing layer 504 may include the same structure, except for the buried gate structure 600G and the second barrier layer 401 illustrated in FIG. 12.

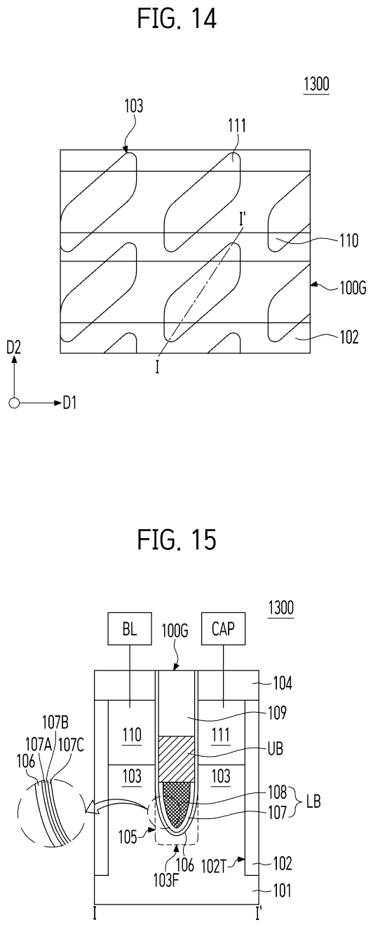

FIG. 14 is a plan view illustrating a semiconductor device in accordance with a 13^{th} embodiment of the present invention. FIG. 15 is a cross-sectional view of the semiconductor device taken along a line I-I′ shown in FIG. 14 in accordance with the 13^{th} embodiment of the present invention.

Referring to FIGS. 14 and 15, the semiconductor device 1300 in accordance with the 13^{th} embodiment of the present invention may include a substrate 101, and a buried gate structure 100G, a first doped region 110, and a second doped region 111 embedded in the substrate 101. The buried gate structure 100G and the first and second doped regions 110 and 111 may form a cell transistor. The cell transistor may improve the short channel effect due to the buried gate structure.

The semiconductor device 1300 may be a portion of a memory cell. For example, the semiconductor device 1300 may be a portion of a DRAM memory cell. The semiconductor device 1300 may include a bit line BL and a memory storage element CAP that are electrically connected to the substrate 101. The bit line BL may be coupled to the first doped region 110, and the memory storage element CAP may be coupled to the second doped region 111. The bit line BL and the memory storage element CAP may be disposed at a higher level than the buried gate structure 100G. The bit lines BL and the memory storage elements CAP may be disposed at different levels. The memory storage element CAP may be disposed at a higher level than the bit line BL. The memory storage element CAP may include a capacitor.

An isolation layer 102 and an active region 103 may be formed over the substrate 101. The active region 103 may be defined by the isolation layer 102. The active region 103 may have a long axis and a short axis. The active region 103 may be tilted in a diagonal direction. One buried gate structure 100G may be formed in one active region 103. The first doped region 110 or the second doped region 111 may be formed in each of the active regions 103 on both sides of the buried gate structure 100G. This embodiment may include one buried gate structure 100G, one first doped region 110, and one second doped region 111 in one active region.

The buried gate structure 100G may be embedded in the trench 105. The buried gate structure 100G may include the same structure as the buried gate structure 100G illustrated in FIG. 2.

According to another embodiment of the present invention, the buried gate structure 100G may include the same structure as the buried gate structures in accordance with the second to 12^{th} embodiments illustrated in FIGS. 3 to 13.

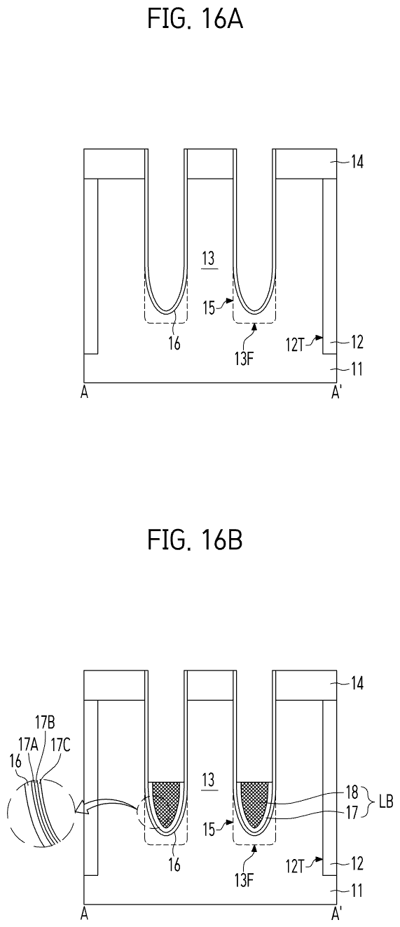

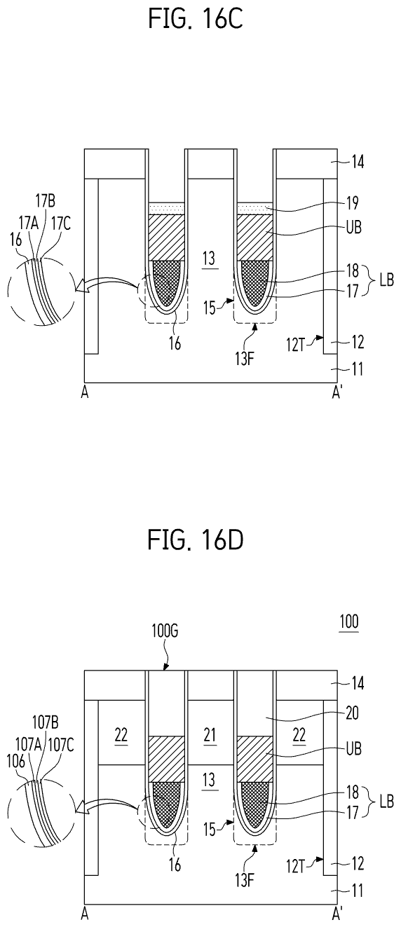

FIGS. 16A to 16D are process cross-sectional views illustrating a method for fabricating a semiconductor device in accordance with a first embodiment of the present invention. FIGS. 16A to 16D illustrate an example of a method for forming the semiconductor device 100 illustrated in FIG. 2A.

Referring to FIG. 16A, an isolation layer 12 may be formed over a substrate 11. The active region 13 may be defined by the isolation layer 12. The isolation layer 12 may be formed by a Shallow Trench Isolation (STI) process. For example, the substrate 11 may be etched to form an isolation trench 12T. The isolation trench 12T may be filled with a dielectric material, thereby forming the isolation layer 12. The isolation layer 12 may include silicon oxide, silicon nitride, or a combination thereof. Chemical Vapor Deposition (CVD) or another deposition process may be performed to fill the isolation trench 12T with a dielectric material. A planarization process such as Chemical-Mechanical Polishing (CMP) may be additionally used.

A trench 15 may be formed in the substrate 11. The trench 15 may be formed in the shape of a line crossing the active region 13 and the isolation layer 12. The trench 15 may be formed by an etching process of the substrate 11 using the hard mask layer 14 as an etch mask. The hard mask layer 14 may be formed over the substrate 11 and may have a line-shaped opening. The hard mask layer 14 may be formed of a material having an etch selectivity with respect to the substrate 11. The hard mask layer 14 may be a silicon oxide, such as Tetra-Ethyl-Ortho-Silicate (TEOS). The trench 15 may be formed shallower than the isolation trench 12T. The depth of the trench 15 may be sufficient to increase the average cross-sectional area of the subsequent gate electrode. Accordingly, the resistance of the gate electrode may be decreased. The lower edge of the trench 15 may have a curvature.

Subsequently, a fin 13F may be formed. To form the fin 13F, the isolation layer 12 below the trench 15 may be selectively recessed. As for the structure of the fin 13F, the fin 103F shown in FIG. 2B may be referred to.

Subsequently, a first gate dielectric layer 16 may be formed on the surface of the trench 15. Before the first gate dielectric layer 16 is formed, etch damage on the surface of the trench 15 may be recovered. For example, after a sacrificial oxide is formed through a thermal oxidation treatment, the sacrificial oxide may be removed.

The first gate dielectric layer 16 may be formed through a thermal oxidation process. The first gate dielectric layer 16 may include silicon oxide.

According to another embodiment of the present invention, the first gate dielectric layer 16 may be formed by Chemical Vapor Deposition (CVD) or Atomic Layer Deposition (ALD). The first gate dielectric layer 16 formed by a deposition process may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may selectively be used. The first gate dielectric layer 16 may include a material having a high oxygen atomic planar density.

Referring to FIG. 16B, a lower buried gate LBG may be formed over the first gate dielectric layer 16 to gap-fill the lower portion of the trench 15. The lower buried gate LBG may include a stacked structure of the first barrier layer 17 and the first gate electrode 18. The lower buried gate LBG may be formed through a series of processes of conformally forming a barrier material over the first gate dielectric layer 16, forming a conductive material to fill the trench 15 over the barrier material, and then performing a recessing process on the barrier material and the conductive material. The recessing process may be performed by a dry etching process, for example, an etch-back process.

The first barrier layer 17 and the first gate electrode 18 may have their top surfaces at the same level. The first gate electrode 18 may be formed over the first barrier layer 17. The first barrier layer 17 may have a liner shape, and the first gate electrode 18 may have a bulk shape. The bottom and outer surfaces of the first gate electrode 18 may be surrounded by the first barrier layer 17.

The first barrier layer 17 may serve to supply oxygen to the first gate electrode 18. The first barrier layer 17 may include a metal-based oxygen material. The first barrier layer 17 may be referred to as an ‘oxygen supply layer 17.’ The first barrier layer 17 may include multiple layers. The first barrier layer 17 may be a multi-layer containing a metal nitride containing oxygen material. The first barrier layer 17 may be a triple layer containing a metal nitride containing oxygen material. The first barrier layer 17 may include a stacked structure of a first metal oxynitride 17A, a metal nitride 17B, and a second metal oxynitride 17C. For example, the first barrier layer 17 may include a stacked structure of the first titanium oxynitride 17A (TiON), the first titanium nitride 17B (TiN), and the second titanium oxynitride 17C (TiON). Here, the first metal oxynitride 17A, the metal nitride 17B, and the second metal oxynitride 17C may be formed through a deposition process. According to another embodiment of the present invention, the second metal oxynitride 17C may be formed by forming the metal nitride 17B and then oxidizing a predetermined thickness of the metal nitride 17B through exposure to the air.

According to another embodiment of the present invention, the first barrier layer 17 may include a stacked structure of the first metal nitride 17A, the metal oxynitride 17B, and the second metal nitride 17C. For example, the first barrier layer 17 may include a stacked structure of the first titanium nitride 17A, the titanium oxynitride 17B (TiON), and the second titanium nitride 17C. Here, the first metal nitride 17A, the metal oxynitride 17B, and the second metal nitride 17C may be formed through a deposition process. According to another embodiment of the present invention, the metal oxynitride 17B may be formed by forming the first metal nitride 17A and then oxidizing a predetermined thickness of the first metal nitride 17A through exposure to the air.

According to yet another embodiment of the present invention, the first barrier layer 17 may be a triple layer including a metal nitride and a metal oxide. The first barrier layer 17 may include a stacked structure of the first metal nitride 17A, the metal oxide 17B, and the second metal nitride 17C. For example, the first barrier layer 17 may include a stacked structure of the first titanium nitride 17A (TiN), the titanium oxide 17B (TiO), and the second titanium nitride 17C (TiN). Here, the first metal nitride 17A, the metal oxide 17B, and the second metal nitride 17C may be formed through a deposition process.

According to yet another embodiment of the present invention, the first barrier layer 17 may include a stacked structure of a metal nitride and a metal oxide. For example, the first barrier layer 17 may include a stacked structure of titanium nitride (TiN) and titanium oxide (TiO). Here, the metal nitride and the metal oxide may be formed through a deposition process.

The first gate electrode 18 may have a high work function. Here, the high work function may refer to a work function that is greater than the mid-gap work function of silicon. A low work function may refer to a work function that is less than the mid-gap work function of silicon. To be specific, the high work function may have a work function which is greater than approximately 4.5 eV, and the low work function may have a work function which is less than approximately 4.5 eV.

According to another embodiment of the present invention, the first gate electrode 18 may have an increased high work function. The first gate electrode 18 may include a metal nitride. The first gate electrode 18 may include a metal nitride containing oxygen material. The first gate electrode 18 may include a metal nitride with a controlled oxygen content. For example, the first gate electrode 18 may include a high-oxygen titanium nitride (high-oxygen TiN). Titanium nitride may have a high work function, and oxygen may be contained in the titanium nitride to further increase the work function of the titanium nitride. The oxygen content of the high-oxygen titanium nitride (high-oxygen TiN) may be greater than the oxygen content of the titanium nitride (TiN). The high-oxygen titanium nitride (high-oxygen TiN) may be formed as the oxygen in the first barrier layer 17 diffuses into the first gate electrode 18 during a heat treatment. The oxygen content of the high-oxygen titanium nitride (high-oxygen TiN) may be adjusted in a range that the work function may be increased while maintaining the resistance of the first gate electrode 18.

Referring to FIG. 16C, the upper buried gate UBG may be formed over the lower buried gate LBG. The upper buried gate UBG may be formed through a series of processes of forming a conductive material to fill the trench 15 over the lower buried gate LBG, and then performing a recessing process on the conductive material. The recessing process may be performed by a dry etching process, for example, an etch-back process.

The upper buried gate UBG may be formed over the lower buried gate LBG. The top surface of the upper buried gate UBG may be disposed at a lower level than the top surface of the active region 13. The upper buried gate UBG may be formed of a low-resistance material to decrease the gate sheet resistance. The upper buried gate UBG may have a low work function. The upper buried gate UBG may include a metal nitride. The upper buried gate UBG may include a metal nitride with a controlled oxygen content. The upper buried gate UBG may include a metal nitride having less oxygen content in the film than the first gate electrode 18. For example, the upper buried gate 18 may include a low-oxygen titanium nitride (low-oxygen TiN). Here, the low-oxygen titanium nitride may refer to titanium nitride that does not contain oxygen in the film or has a minimal oxygen content. The oxygen content of the low-oxygen titanium nitride (low-oxygen TiN) may be lower than the oxygen content of titanium nitride (TiN).

Subsequently, a sacrificial layer 19 may be formed over the upper buried gate UBG. The sacrificial layer 19 may prevent the work function of the upper buried gate UBG from increasing by capturing the oxygen on the surface of the upper buried gate UBG. The sacrificial layer 19 may include a silicon material. For example, the sacrificial layer 19 may include polysilicon.

Subsequently, a heat treatment may be performed. When a heat treatment is performed, titanium oxide (TiOₓ) produced through an oxidation of the surface of the upper buried gate UBG may be substituted with silicon oxide (SiO₂). After titanium oxide (TiOₓ) is substituted with silicon oxide, the oxygen on the surface of the upper buried gate UBG does not penetrate or diffuse into the upper buried gate UBG anymore.

Subsequently, the sacrificial layer 19 may be removed. The sacrificial layer 19 may be removed by a wet etching process. When the sacrificial layer 19 is removed, the substituted silicon oxide (SiO₂) may be removed together.

Referring to FIG. 16D, a capping layer 20 that gap-fills the remaining portion of the trench 15 may be formed over the upper buried gate UBG. The capping layer 20 may include a dielectric material. The capping layer 20 may include silicon nitride. Subsequently, the capping layer 20 may be planarized to expose the top surface of the hard mask layer 14. The capping layer 20 may have an Oxide-Nitride-Oxide (ONO) structure.

Subsequently, a first doped region 21 and second doped regions 22 may be formed in the substrate 11. The first and second doped regions 21 and 22 may be formed by doping an impurity into the substrate 11 through an implantation process or another doping process.

Through a series of the processes as described above, the buried gate structure 100G may be formed.

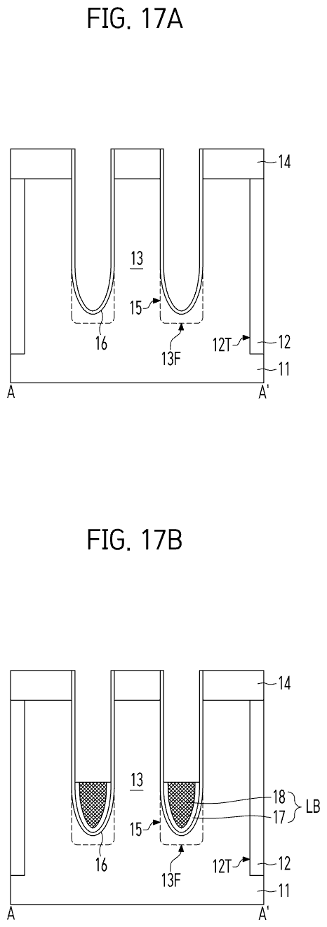

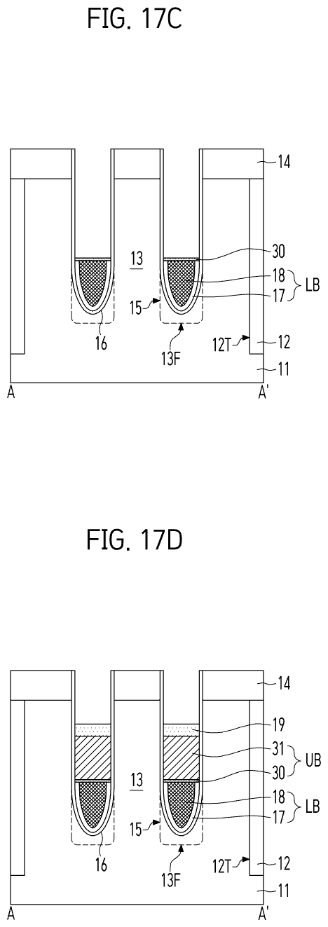

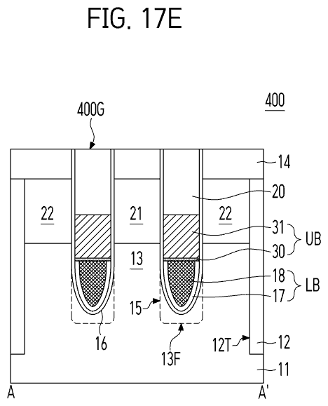

FIGS. 17A to 17E are process cross-sectional views illustrating a method for fabricating a semiconductor device in accordance with a fourth embodiment of the present invention. FIGS. 17A to 17E illustrate an example of a method for forming the semiconductor device 400 shown in FIG. 5.

Referring to FIG. 17A, an isolation layer 12 may be formed over the substrate 11. The active region 13 may be defined by the isolation layer 12. The isolation layer 12 may be formed by a Shallow Trench Isolation (STI) process. For example, the substrate 11 may be etched to form an isolation trench 12T. The isolation trench 12T may be filled with a dielectric material, thereby forming the isolation layer 12. The isolation layer 12 may include silicon oxide, silicon nitride, or a combination thereof. Chemical Vapor Deposition (CVD) or another deposition process may be performed to fill the isolation trench 12T with a dielectric material. A planarization process, such as Chemical-Mechanical Polishing (CMP), may be additionally performed.

A trench 15 may be formed in the substrate 11. The trench 15 may be formed in the shape of a line crossing the active region 13 and the isolation layer 12. The trench 15 may be formed by using the hard mask layer 14 as an etch mask and performing an etching process on the substrate 11. The hard mask layer 14 may be formed over the substrate 11 and may have a line-shaped opening. The hard mask layer 14 may be formed of a material having an etch selectivity with respect to the substrate 11. The hard mask layer 14 may be a silicon oxide, such as Tetra-Ethyl-Ortho-Silicate (TEOS). The trench 15 may be formed shallower than the isolation trench 12T. The depth of the trench 15 may be sufficient to increase the average cross-sectional area of the subsequent gate electrode. Accordingly, the resistance of the gate electrode may be decreased. The lower edge of the trench 15 may have a curvature.

Subsequently, a fin 13F may be formed. To form the fin 13F, the isolation layer 12 below the trench 15 may be selectively recessed. As for the structure of the fin 13F, the fin 103F of FIG. 5 may be referred to.

Subsequently, the first gate dielectric layer 16 may be formed on the surface of the trench 15. Before the first gate dielectric layer 16 is formed, the etch damage on the surface of the trench 15 may be recovered. For example, after a sacrificial oxide is formed through a thermal oxidation treatment, the sacrificial oxide may be removed.

The first gate dielectric layer 16 may be formed through a thermal oxidation process. The first gate dielectric layer 16 may include silicon oxide.

According to another embodiment of the present invention, the first gate dielectric layer 16 may be formed by Chemical Vapor Deposition (CVD) or Atomic Layer Deposition (ALD). The first gate dielectric layer 16 formed by a deposition method may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to other embodiments of the present invention, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may be selectively used. The first gate dielectric layer 16 may include a material having a high oxygen atomic planar density.

Referring to FIG. 17B, a lower buried gate LBG may be formed over the first gate dielectric layer 16 to gap-fill the lower portion of the trench 15. The lower buried gate LBG may include a stacked structure of the first barrier layer 17 and the first gate electrode 18. The lower buried gate LBG may be formed through a series of processes of conformally forming a barrier material over the first gate dielectric layer 16, forming a conductive material over the barrier material to fill the trench 15, and then performing a recessing process on the barrier material and the conductive material. The recessing process may be performed by a dry etching process, for example, an etch-back process.

The first barrier layer 17 and the first gate electrode 18 may have their top surfaces at the same level. The first gate electrode 18 may be formed over the first barrier layer 17. The first barrier layer 17 may have a liner shape, and the first gate electrode 18 may have a bulk shape. The bottom and outer surfaces of the first gate electrode 18 may be surrounded by the first barrier layer 17.

The first barrier layer 17 may serve to supply oxygen to the first gate electrode 18. The first barrier layer 17 may include a metal-based oxygen material. The first barrier layer 17 may be referred to as an ‘oxygen supply layer.’ The first barrier layer 17 may include multiple layers. The first barrier layer 17 may be a multi-layer containing a metal nitride containing oxygen material. The first barrier layer 17 may be a triple layer containing a metal nitride containing oxygen material. The first barrier layer 17 may include a stacked structure of a first metal oxynitride 17A, a metal nitride 17B, and a second metal oxynitride 17C. For example, the first barrier layer 17 may include a stacked structure of a first titanium oxynitride 17A (TiON), a first titanium nitride 17B (TiN), and a second titanium oxynitride 17C (TiON). Here, the first metal oxynitride 17A, a metal nitride 17B, and a second metal oxynitride 17C may be formed through a deposition process. According to another embodiment of the present invention, the second metal oxynitride 17C may be formed by forming the metal nitride 17B and then oxidizing a predetermined thickness of the metal nitride 17B through exposure to the air.

According to another embodiment of the present invention, the first barrier layer 17 may include a stacked structure of the first metal nitride 17A, the metal oxynitride 17B, and the second metal nitride 17C. For example, the first barrier layer 17 may include a stacked structure of the first titanium nitride 17A, the titanium oxynitride 17B (TiON), and the second titanium nitride 17C. Here, the first metal nitride 17A, the metal oxynitride 17B, and the second metal nitride 17C may be formed through a deposition process. According to another embodiment of the present invention, the metal oxynitride 17B may be formed by forming the first metal nitride 17A and then oxidizing a predetermined thickness of the first metal nitride 17A through exposure to the air.

According to yet another embodiment of the present invention, the first barrier layer 17 may be a triple layer including a metal nitride and a metal oxide. The first barrier layer 17 may include a stacked structure of the first metal nitride 17A, the metal oxide 17B, and the second metal nitride 17C. For example, the first barrier layer 17 may include a stacked structure of the first titanium nitride 17A (TiN), the titanium oxide 17B (TiO), and the second titanium nitride 17C (TiN). Here, the first metal nitride 17A, the metal oxide 17B, and the second metal nitride 17C may be formed through a deposition process.

According to yet another embodiment of the present invention, the first barrier layer 17 may include a stacked structure of a metal nitride and a metal oxide. For example, the first barrier layer 17 may include a stacked structure of titanium nitride (TiN) and titanium oxide (TiO). Here, the metal nitride and the metal oxide may be formed through a deposition process.

The first gate electrode 18 may have a high work function. Here, the high work function may refer to a work function that is greater than the mid-gap work function of silicon. A low work function may refer to a work function that is less than the mid-gap work function of silicon. To be specific, the high work function may have a work function which is greater than approximately 4.5 eV, and the low work function may have a work function which is less than approximately 4.5 eV.

According to another embodiment of the present invention, the first gate electrode 18 may have an increased high work function. The first gate electrode 18 may include a metal nitride. The first gate electrode 18 may include a metal nitride containing oxygen material. The first gate electrode 18 may include a metal nitride with a controlled oxygen content. For example, the first gate electrode 18 may include a high-oxygen titanium nitride (high-oxygen TiN). Titanium nitride may have a high work function, and oxygen may be contained in the titanium nitride to further increase the work function of the titanium nitride. The oxygen content of the high-oxygen titanium nitride (high-oxygen TiN) may be greater than the oxygen content of titanium nitride (TiN). The high-oxygen titanium nitride (high-oxygen TiN) may be formed as the oxygen in the first barrier layer 17 diffuses into the first gate electrode 18 during a heat treatment. The oxygen content of the high-oxygen titanium nitride (high-oxygen TiN) may be adjusted in a range that the work function may be increased while maintaining the resistance of the first gate electrode 18.

Referring to FIG. 17C, a second barrier layer 30 may be formed over the lower buried gate LBG.

The second barrier layer 30 may be formed through a deposition process or a treatment process. The second barrier layer 30 may be formed by performing a deposition process ex-situ with a subsequent second gate electrode. According to another embodiment of the present invention, the second barrier layer 30 may be formed in-situ with the subsequent second gate electrode through a treatment of monosilane (SiH₄) that is present in the processing equipment for forming the second gate electrode. The second barrier layer 30 may include a silicon-based material. For example, the second barrier layer 30 may include polysilicon. The second barrier layer 30 may be adjusted to have a minimal thickness capable of capturing oxygen without increasing the device resistance. The second barrier layer 30 may be adjusted to have a thickness that does not exceed at least approximately 2 nm. That is, the second barrier layer 30 may be formed to have a thickness of approximately 2 nm or less.

The second barrier layer 30 may capture the oxygen on the surface of the first gate electrode 18. Also, the second barrier layer 30 may serve as a barrier that separates the first gate electrode 18 and the subsequent second gate electrode from each other and prevent the migration of oxygen or metal ions between them. The second barrier layer 30 may be referred to as an ‘oxygen capturing layer 30.’ The second barrier layer 30 may capture the oxygen on the surface of the first gate electrode 18 and prevent the oxygen on the surface of the first gate electrode 18 from diffusing into the subsequent second gate electrode. The second barrier layer 30 may also be referred to as an ‘oxygen diffusion prevention layer 30.’

Referring to FIG. 17D, the upper buried gate UBG may be formed by stacking a second gate electrode 31 over the second barrier layer 30. The second gate electrode 31 may be formed through a series of processes of forming a conductive material over the second barrier layer 30 to fill the trench 15, and then performing a recessing process on the conductive material. The recessing process may be performed by a dry etching process, for example, an etch-back process.

The second gate electrode 31 may be formed of a low-resistance material to decrease the gate sheet resistance. The second gate electrode 31 may have a low work function. The second gate electrode 31 may include a metal nitride. The second gate electrode 31 may include a metal nitride with a controlled oxygen content. The second gate electrode 31 may include a metal nitride having less oxygen content in the film than the first gate electrode 18. For example, the second gate electrode 31 may include a low-oxygen titanium nitride (low-oxygen TiN). Here, the low-oxygen titanium nitride may refer to titanium nitride that does not contain oxygen in the film or has a minimal oxygen content. The oxygen content of the low-oxygen titanium nitride (low-oxygen TiN) may be less than the oxygen content of titanium nitride (TiN).

Subsequently, the sacrificial layer 19 may be formed over the second gate electrode 31. The sacrificial layer 19 may prevent the work function of the second gate electrode 31 from increasing by capturing the oxygen on the surface of the second gate electrode 31. The sacrificial layer 19 may include a silicon material. For example, the sacrificial layer 19 may include polysilicon.

Subsequently, a heat treatment may be performed. When the heat treatment is performed, titanium oxide (TiOₓ) produced by oxidizing the surface of the second gate electrode 31 may be substituted with silicon oxide (SiO₂), and after the titanium oxide (TiOₓ) is substituted with silicon oxide, the oxygen on the surface of the second gate electrode 31 does not penetrate or diffuse into the second gate electrode 31 anymore.

Subsequently, the sacrificial layer 19 may be removed. The sacrificial layer 19 may be removed by a wet etching process. When the sacrificial layer 19 is removed, the substituted silicon oxide (SiO₂) may be removed together.

Referring to FIG. 17E, a capping layer 20 that gap-fills the remaining portion of the trench 15 may be formed over the upper buried gate UBG. The capping layer 20 may include a dielectric material. The capping layer 20 may include silicon nitride. Subsequently, the capping layer 20 may be planarized to expose the top surface of the hard mask layer 14. The capping layer 20 may have an Oxide-Nitride-Oxide (ONO) structure.

Subsequently, the first doped region 21 and the second doped regions 22 may be formed in the substrate 11. The first and second doped regions 21 and 22 may be formed by doping an impurity into the substrate 11 by using an implantation process or another doping process.

Through a series of the processes described above, the buried gate structure 400G may be formed.

According to the embodiments of the present invention, gate-induced drain leakage (GIDL) may be improved by adjusting the work functions of the upper and lower gate electrodes.

According to the embodiments of the present invention, the resistance of the word line may be decreased by applying a gate electrode containing a metal material.

While the embodiments of the present invention have been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device, comprising:
a trench formed in a substrate;
a first gate filled in a lower portion of the trench; and
a second gate disposed over the first gate,
wherein each of the first gate and the second gate contains oxygen material, and an oxygen content of the first gate is greater than an oxygen content of the second gate.

2. The semiconductor device of claim 1, wherein the first gate includes a stacked structure of an oxygen supply layer and a first conductive layer, the oxygen supply layer supplying oxygen to the first conductive layer.

3. The semiconductor device of claim 2, wherein the oxygen supply layer includes a metal-based oxygen material.

4. The semiconductor device of claim 2, wherein the oxygen supply layer includes titanium oxynitride.

5. The semiconductor device of claim 2, wherein the oxygen supply layer and the first conductive layer include the same metal material.

6. The semiconductor device of claim 2, wherein the oxygen supply layer includes multiple oxygen supplying layers.

7. The semiconductor device of claim 1, wherein the second gate includes
a low-oxygen titanium nitride (low-oxygen TiN) whose oxygen content is less than an oxygen content of titanium nitride (TiN).

8. The semiconductor device of claim 1, wherein the second gate includes one selected from among
a stacked structure of a second conductive layer, a first oxygen capturing layer, a third conductive layer, and a second oxygen capturing layer,
a stacked structure of a second conductive layer, a first oxygen capturing layer, and a third conductive layer, and
a stacked structure of a second conductive layer and a first oxygen capturing layer.

9. The semiconductor device of claim 8, wherein the second conductive layer covers an outer surface of the first oxygen capturing layer.

10. The semiconductor device of claim 8, wherein the first oxygen capturing layer has a thickness which is less than a thickness of the second conductive layer.

11. The semiconductor device of claim 8, wherein each of the second and third conductive layers include a low-oxygen titanium nitride (low-oxygen TiN) whose oxygen content is less than an oxygen content of titanium nitride (TiN).

12. The semiconductor device of claim 8, wherein each of the first and second oxygen capturing layers include polysilicon.

13. The semiconductor device of claim 1, further comprising:
a first gate dielectric layer between a structure of the first and second gates and an inner surface of the trench, and
a second gate dielectric layer extending from a space between the first gate and the second gate to a space between the second gate and the first gate dielectric layer.

14. The semiconductor device of claim 1, further comprising:
a barrier layer between the first gate and the second gate.

15. The semiconductor device of claim 14, wherein the barrier layer includes polysilicon.

16. The semiconductor device of claim 14, further comprising:
a first gate dielectric layer between a structure of the first and second gates and an inner surface of the trench,
wherein the barrier layer extends to a space between the second gate and the first gate dielectric layer.

17. The semiconductor device of claim 13, further comprising:
a barrier layer between the first gate and the second gate dielectric layer.

18. A method for fabricating a semiconductor device, the method comprising:
forming a trench in a substrate;
forming a first gate that fills a lower portion of the trench;
forming a second gate over the first gate;
forming a sacrificial layer over the second gate;
substituting a surface of the second gate with silicon oxide by performing a heat treatment; and
removing the sacrificial layer and the silicon oxide,
wherein each of the first and second gates contains oxygen material, and an oxygen content of the first gate is greater than an oxygen content of the second gate.

19. The method of claim 18, further comprising:
before forming he first gate,
forming a gate dielectric layer that covers bottom and inner surfaces of the trench.

20. The method of claim 18, wherein forming the first gate includes:
forming an oxygen supply layer; and
forming a first conductive layer over the oxygen supply layer supplying oxygen to the first conductive layer.

21. The method of claim 20, wherein the oxygen supply layer includes titanium oxynitride, and
the first conductive layer includes a high-oxygen titanium nitride (TiN) whose oxygen content is greater than an oxygen content of titanium nitride (TiN).

22. The method of claim 18, further comprising:
before forming the second gate,
forming a barrier layer over the first gate.

23. The method of claim 22, wherein the barrier layer extends to an outer surface of the second gate.

24. The method of claim 22, wherein forming the barrier layer includes
performing a polysilicon deposition process.

25. The method of claim 22, wherein forming the barrier layer includes
performing a treatment process using monosilane (SiH₄) in a chamber for the second gate, before forming the second gate.

26. The method of claim 18, further comprising:
forming a first gate dielectric layer that covers bottom and inner surfaces of the trench, before forming the first gate, and
forming a second gate dielectric layer over the first gate and over the first gate dielectric layer exposed by the first gate, before forming the second gate.

27. The method of claim 18, wherein the second gate includes
a low-oxygen titanium nitride (low-oxygen TiN) whose oxygen content is less than an oxygen content of titanium nitride (TiN).

28. The method of claim 18, wherein the second gate includes one selected from among
a stacked structure of a first low-oxygen titanium nitride, a first oxygen capturing layer, a second low-oxygen titanium nitride, and a second oxygen capturing layer,
a stacked structure of a first low-oxygen titanium nitride, a first oxygen capturing layer, and a second low-oxygen titanium nitride, and
a stacked structure of a first low-oxygen titanium nitride and a first oxygen capturing layer.
